(19) United States
(12) Patent Application Publication
(10) Pub. No.: US 2025/0324526 A1
(43) Pub. Date: Oct. 16, 2025

(54) APPARATUS FOR ETCHING COVER WINDOW FOR DISPLAY DEVICE AND METHOD FOR ETCHING COVER WINDOW FOR DISPLAY DEVICE USING THE SAME

(71) Applicant: Samsung Display Co., LTD., Yongin-si (KR)

(72) Inventors: SEUNGPYO HONG, Yongin-si (KR); DONGHO KIM, Yongin-si (KR); HYUNCHUL KIM, Yongin-si (KR); JUNHEE BAE, Yongin-si (KR); BYOUNGYUL SHIM, Yongin-si (KR); KANG DUK CHOI, Yongin-si (KR)

(21) Appl. No.: 19/065,572

(22) Filed: Feb. 27, 2025

(30) Foreign Application Priority Data
Apr. 16, 2024 (KR) 10-2024-0051012
Jul. 23, 2024 (KR) 10-2024-0097149

(51) Int. Cl. H05K 5/03

(52) U.S. Cl. CPC H05K 5/03

(57) ABSTRACT

An apparatus for etching a cover window for a display device includes a lower jig in which an accommodation groove, in which a cover window made of a glass material is disposed, is defined and an upper jig disposed on the lower jig, wherein a bottom surface of the upper jig, which faces the lower jig and which has first sides extending in a first direction and second sides extending in a second direction intersecting with the first direction, includes a first surface configured to define an etching groove extending in the first direction and a second surface disposed adjacent to the first surface.

This application claims priority to Korean Patent Application No. 10-2024-0051012, filed on Apr. 16, 2024, and Korean Patent Application No. 10-2024-0097149, filed on Jul. 23, 2024, and all the benefits accruing therefrom under 35 U.S.C. § 119, the contents of which in their entireties are herein incorporated by reference.

### BACKGROUND

### 1. Field

The invention relates to an apparatus for etching a cover window, and more particularly to an apparatus for etching a cover window for a display device and a method for etching the cover window for the display device using the apparatus.

### 2. Description of Related Art

An electronic device displays various images on a display screen to provide information to a user. Generally, the electronic device displays the information within an allocated screen area. Recently, flexible electronic devices, which include a foldable, flexible display panel, have been developed. Unlike rigid electronic devices, flexible electronic devices may be folded, rolled, or bent. Flexible electronic devices, whose shapes may be variably changed, offer enhanced portability without being constrained by the existing screen size, thereby improving user convenience.

The electronic device includes a display panel and a cover window disposed on the display panel to protect the display panel.

### SUMMARY

The invention provides an apparatus for etching a cover window having improved etching efficiency and which is capable of easily manufacturing cover windows having shapes different from each other.

The invention also provides an apparatus for etching a cover window capable of easily removing residues generated on a surface of the cover window when the cover window is etched.

An embodiment provides an apparatus for etching a cover window for a display device, wherein the apparatus includes a lower jig in which an accommodation groove for placing a glass cover window is defined, and an upper jig disposed on the lower jig, wherein a bottom surface of the upper jig, which faces the lower jig and which has first sides extending in a first direction and second sides extending in a second direction intersecting with the first direction, includes a first surface defining an etching groove extending in the first direction, and a second surface disposed adjacent to the first surface.

In an embodiment, a method for etching a cover window for a display device includes placing a preliminary cover window, which comprises non-etching areas arranged in a first direction and an etching area disposed between the non-etching areas, in an accommodation groove defined in a lower jig to fix the preliminary cover window in place, placing an upper jig, which has an etching groove extending in the first direction defined in a bottom surface thereof facing the lower jig, on the lower jig to cover the preliminary cover window, introducing an etchant into the etching groove through an inlet pipe disposed on a top surface of the upper jig and connected to the etching groove to etch an etching area and discharging the etchant from the etching groove through an outlet pipe disposed on the top surface of the upper jig and spaced apart from the inlet pipe in the first direction, wherein the bottom surface of the upper jig, which has first sides extending in the first direction and second sides extending in the second direction intersecting with the first direction, includes, a first surface defining the etching groove and a second surface disposed adjacent to the first surface, wherein a folding groove is defined in the etched etching area, and wherein the folding groove has a shape corresponding to that of the etching groove.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1 is a perspective view of an apparatus for etching a cover window, according to an embodiment;

FIG. 2 is an exploded perspective view of the apparatus for etching the cover window shown in FIG. 1, according to an embodiment;

FIG. 3A is a plan view of a bottom surface of an upper jig shown in FIG. 2, according to an embodiment;

FIG. 3B is a cross-sectional view of a portion corresponding to line I-I′ shown in FIG. 2, according to an embodiment;

FIG. 4 is a perspective view of an electronic device including a cover window manufactured by the apparatus for etching the cover window shown in FIG. 1, according to an embodiment;

FIG. 5 is a view showing a folded state of the electronic device shown in FIG. 4, according to an embodiment;

FIG. 6 is an exploded perspective view of the electronic device shown in FIG. 4, according to an embodiment;

FIG. 7A is a cross-sectional view of the cover window shown in FIG. 4, according to an embodiment;

FIG. 7B is a cross-sectional view of the cover window shown in FIG. 4, according to an embodiment;

FIG. 7C is a cross-sectional view of the cover window shown in FIG. 4, according to an embodiment;

FIG. 8A is a view for explaining a method for manufacturing the cover window using the apparatus for etching the cover window shown in FIG. 1, according to an embodiment;

FIG. 8B is a view for explaining a method for manufacturing the cover window using the apparatus for etching the cover window shown in FIG. 1, according to an embodiment;

FIG. 8C is a view for explaining a method for manufacturing the cover window using the apparatus for etching the cover window shown in FIG. 1, according to an embodiment;

FIG. 8D is a view for explaining a method for manufacturing the cover window using the apparatus for etching the cover window shown in FIG. 1, according to an embodiment;

FIG. 8E is a view for explaining a method for manufacturing the cover window using the apparatus for etching the cover window shown in FIG. 1, according to an embodiment;

FIG. 8F is a view for explaining a method for manufacturing the cover window using the apparatus for etching the cover window shown in FIG. 1, according to an embodiment;

FIG. 8G is a view for explaining a method for manufacturing the cover window using the apparatus for etching the cover window shown in FIG. 1, according to an embodiment;

FIG. 9A is a perspective view of an apparatus for etching a cover window, according to an embodiment;

FIG. 9B is a cross-sectional view of a portion corresponding to line IV-IV′ shown in FIG. 9A, according to an embodiment;

FIG. 10A is a cross-sectional view for explaining an upper jig, according to an embodiment;

FIG. 10B is a cross-sectional view for explaining an upper jig, according to an embodiment;

FIG. 11 is a view for explaining a dry film resist, according to an embodiment;

FIG. 12A is a view for explaining an upper jig, according to an embodiment;

FIG. 12B is a view for explaining an upper jig, according to an embodiment;

FIG. 13A is a view for explaining an upper jig, according to an embodiment;

FIG. 13B is a view for explaining an upper jig, according to an embodiment;

FIG. 14A is a view for explaining an etching of a preliminary cover window using the upper jig shown in FIGS. 13A and 13B, according to an embodiment;

FIG. 14B is a view for explaining an etching of a preliminary cover window using the upper jig shown in FIGS. 13A and 13B, according to an embodiment;

FIG. 15 is a plan view showing a bottom surface of the upper jig, according to an embodiment; and

FIG. 16 is a view for explaining an etching device, according to an embodiment.

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

Like numbers refer to like elements throughout. The thickness and the ratio and the dimension of the element are exaggerated for effective description of the technical contents.

As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

The terminology used herein is for the purpose of describing particular embodiments only and is not intended to be limiting of the invention. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, the invention will be explained in detail with reference to the accompanying drawings.

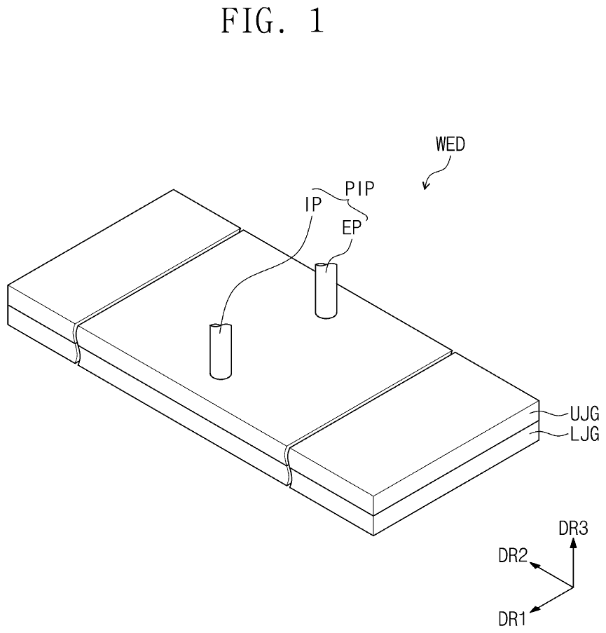

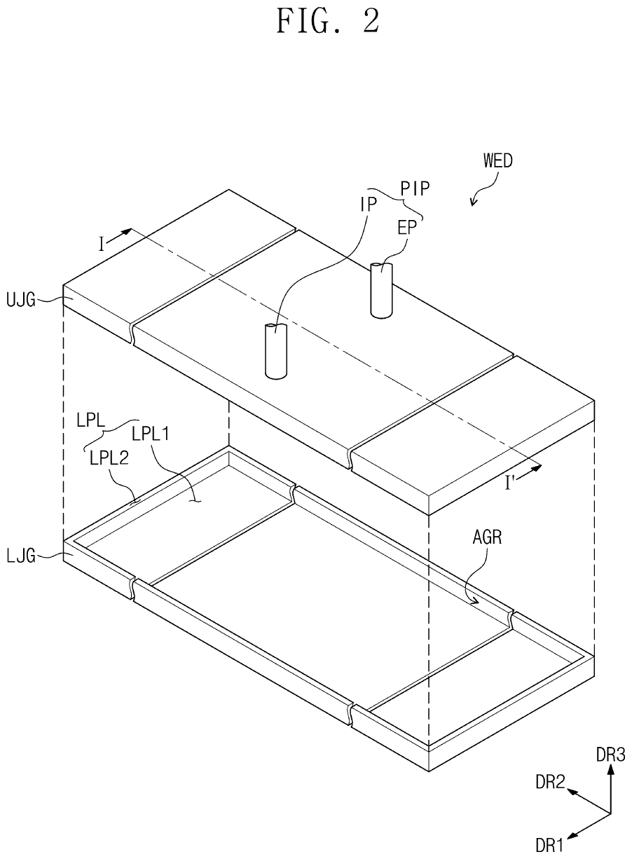

FIG. 1 is a perspective view of an apparatus for etching a cover window, according to an embodiment. FIG. 2 is an exploded perspective view of the apparatus for etching the cover window shown in FIG. 1, according to an embodiment.

In an embodiment and referring to FIGS. 1 and 2, an apparatus WED for etching a cover window etching device may include a lower jig LJG, an upper jig UJG, and a plurality of pipes PIP. The lower jig LJG may have a rectangular parallelepiped shape with short sides extending in the first direction DR1 and long sides extending in the second direction DR2, which intersects the first direction DR1. However, the shape of the lower jig LJG is not limited thereto.

Hereinafter, the direction intersecting the first direction DR1 is defined as the second direction DR2. Additionally, the direction that substantially perpendicularly intersects the plane defined by the first and second directions DR1 and DR2 is defined as the third direction DR3. In this specification, the term “when viewed on a plane” may refer to a view from the third direction DR3.

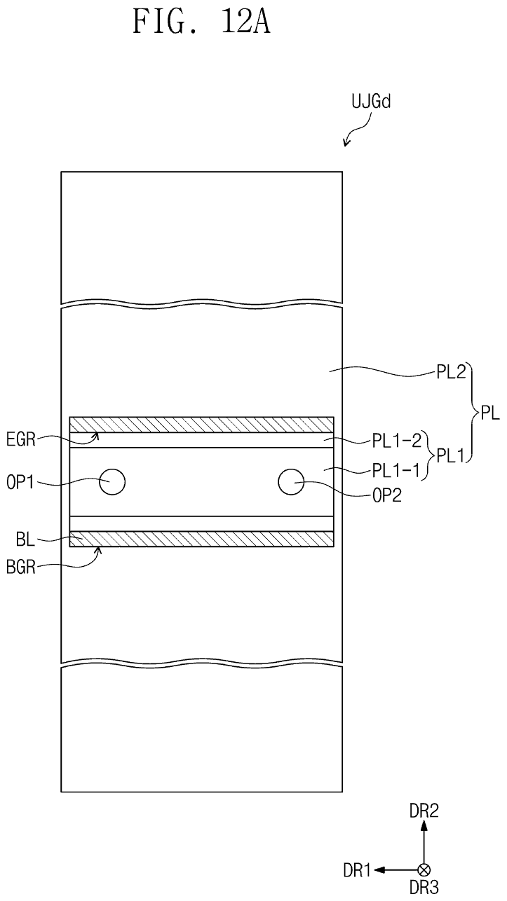

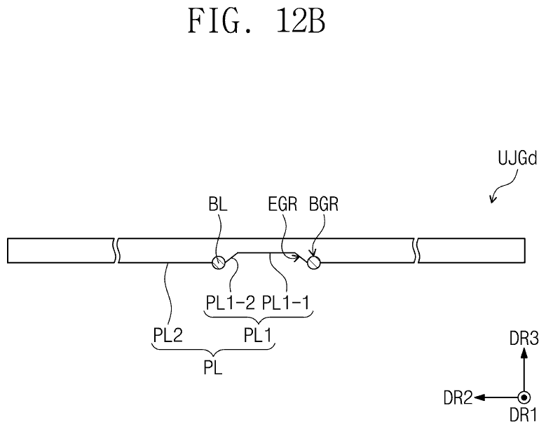

In an embodiment, an accommodation groove AGR may be defined in a top surface LPL of the lower jig LJG, where the accommodation groove AGR may extend from the top surface LPL of the lower jig LJG toward a bottom surface of the lower jig LJG in the third direction DR3. A preliminary cover window PWM (see FIG. 12A), which will be described later, may be disposed in the accommodation groove AGR.

In an embodiment, the top surface LPL of the lower jig LJG may include a first top surface LPL1 and a second top surface LPL2. The first top surface LPL1 may be defined as a bottom surface of the accommodation groove AGR and the second top surface LPL2 may be defined as a remaining portion of the top surface LPL of the lower jig LJG, excluding the first top surface LPL1. The first top surface LPL1 and the second top surface LPL2 may be arranged at different levels. The first top surface LPL1 may have a height that is lower than that of the second top surface LPL2. When viewed on the plan, the second top surface LPL2 may surround the first top surface LPL1.

In an embodiment, the upper jig UJG may be disposed on the lower jig LJG, where the upper jig UJG may be disposed on the second top surface LPL2 of the lower jig LJG. The upper jig UJG may have a rectangular parallelepiped shape with short sides extending in the first direction DR1 and long sides extending in the second direction DR2. The upper jig UJG may have a shape corresponding to that of the lower jig LJG and may have a length directed in the first direction DR1 and a length directed in the second direction DR2 that are the same as those of the lower jig LJG, respectively. However, this is only an example, and the shape of the upper jig UJG is not limited thereto.

In an embodiment, the pipes PIP may be disposed on a top surface of the upper jig UJG and may include an inlet pipe IP and an outlet pipe EP. The inlet pipe IP and the outlet pipe EP may be disposed on the top surface of the upper jig UJG.

In an embodiment, the inlet pipe IP and the outlet pipe EP may be spaced apart from each other in the first direction DR1. An etchant may be introduced into the upper jig UJG through the inlet pipe IP and the etchant may flow within the upper jig UJG and may be discharged to the outside through the outlet pipe EP.

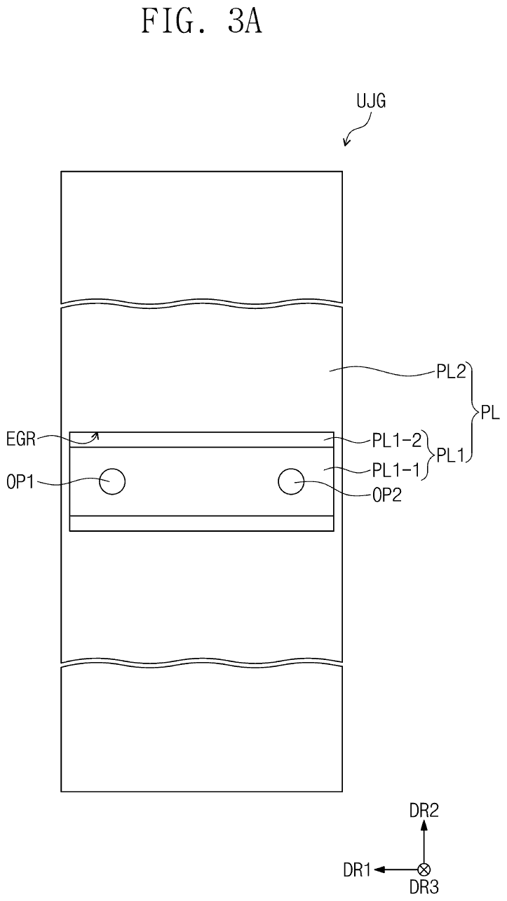

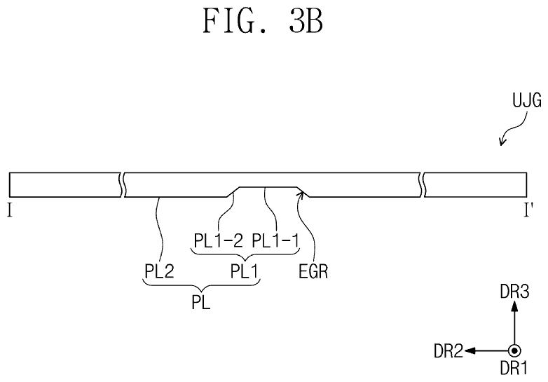

FIG. 3A is a plan view of the bottom surface of the upper jig UJG shown in FIG. 2, according to an embodiment. FIG. 3B is a cross-sectional view of a portion corresponding to line I-I′ shown in FIG. 2, according to an embodiment.

In an embodiment, for example, in FIG. 3B, the lower jig LJG and the pipes PIP are omitted.

In an embodiment, among the elements shown in FIGS. 3A and 3B, the description of elements that are the same as those described with reference to the previous drawings will be omitted or briefly described.

In an embodiment and referring to FIGS. 3A and 3B, when viewed on the plane, the bottom surface PL of the upper jig UJG facing the lower jig LJG (see FIG. 2) may have a rectangular shape with short sides extending in the first direction DR1 and long sides extending in the second direction DR2. Hereinafter, the short sides may be referred to as first sides, and the long sides may be referred to as second sides.

In an embodiment, an etching groove EGR may be defined in the bottom surface PL of the upper jig UJG. When viewed on the plane, the etching groove EGR may extend in the first direction DR1. The etching groove EGR may have a length, which is constant in the second direction DR2.

In an embodiment, when viewed from the first direction DR1, an etching groove EGR may extend in the third direction DR3 from the bottom surface PL of the upper jig UJG. The etching groove EGR may be defined by a portion of the bottom surface PL of the upper jig UJG that is being recessed. The etching groove EGR may have a shape corresponding to a portion of a trapezoid. However, this is only an example, and the shape of the etching groove EGR is not limited thereto.

In an embodiment, the etching groove EGR may overlap the etching area EA (see FIG. 12F) of the preliminary cover window PWM (see FIG. 12F). When the etchant is introduced into the etching groove EGR, the etchant may etch the etching area EA. The etching of the preliminary cover window PWM (see FIG. 12F) will be described in detail with reference to FIGS. 12F and 12G.

In an embodiment, the bottom surface PL of the upper jig UJG may include a first surface PL1 and a second surface PL2, where the first surface PL1 may be defined as inner surfaces of the upper jig UJG that define the etching groove EGR. The second surface PL2 may be defined as remaining surfaces of the bottom surface PL of the upper jig UJG, excluding the first surface PL1. When viewed on the plane, the second surface PL2 may surround the first surface PL1. When viewed from the first direction DR1, the first surface PL1 may have a height greater than that of the second surface PL2.

In an embodiment, the first surface PL1 may include a (1-1)-th surface PL1-1 and a plurality of (1-2)-th surfaces PL1-2. The (1-1)-th surface PL1-1 may be a plane defined by the first direction DR1 and the second direction DR2. When viewed on the plane, the (1-2)-th surfaces PL1-2 may be disposed on both sides of the (1-1)-th surface PL1-1, which oppose each other in the second direction DR2. When viewed from the first direction DR1, the (1-1)-th surface PL1-1 and the (1-2)-th surfaces PL1-2 may form a predetermined angle with each other. The (1-2)-th surfaces PL1-2 may extend at a predetermined angle from both sides of the (1-1)-th surface PL1-1, which oppose each other in the second direction DR2. The (1-2)-th surfaces PL1-2 may be inclined.

In an embodiment and referring to FIGS. 1 and 3A, first and second openings OP1 and OP2 may be defined in the (1-1)-th surface PL1-1, where the first opening OP1 and the second opening OP2 may be disposed adjacent to both sides of the (1-1)-th surface PL1-1, which oppose each other in the first direction DR1. Additionally, the first opening OP1 and the second opening OP2 may be spaced apart from each other in the first direction DR1.

In an embodiment, the first opening OP1 may be connected to the inlet pipe IP shown in FIG. 1 and the second opening OP2 may be connected to the outlet pipe EP. The first opening OP1 may be defined in continuity with an internal space of the inlet pipe IP and the second opening OP2 may be defined in continuity with an internal space of the outlet pipe EP. Accordingly, the etchant flowing inside the inlet pipe IP may be introduced into the etching groove EGR through the first opening OP1 and then discharged to the outlet pipe EP through the second opening OP2.

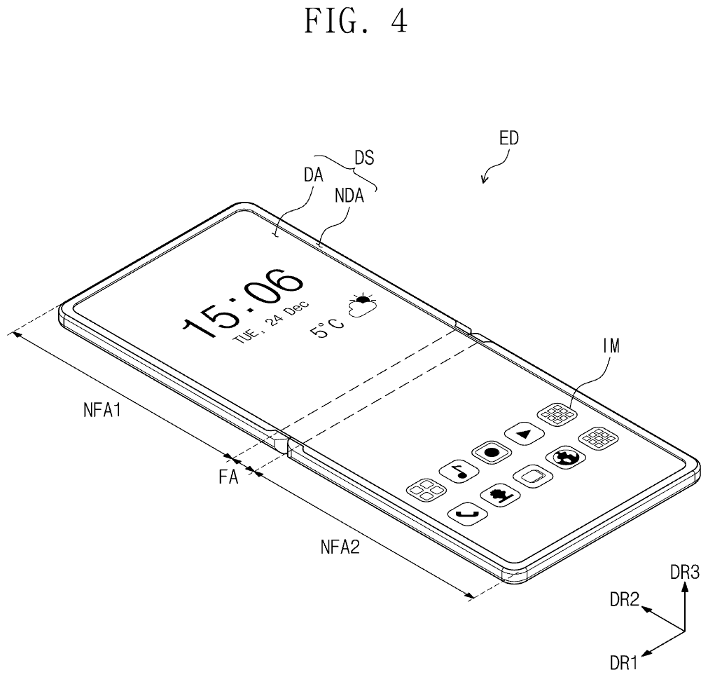

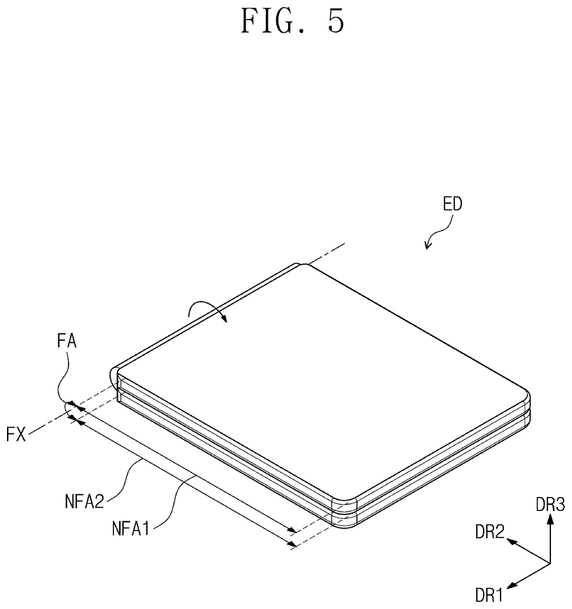

FIG. 4 is a perspective view of an electronic device including a cover window manufactured by the apparatus for etching the cover window shown in FIG. 1, according to an embodiment. FIG. 5 is a view showing a folded state of the electronic device shown in FIG. 4, according to an embodiment.

In an embodiment and referring to FIG. 4, the electronic device ED may have a rectangular shape with short sides extending in the first direction DR1 and long sides extending in the second direction DR2. However, the electronic device ED is not limited thereto and may have various shapes such as circular or polygonal. The electronic device ED may be a flexible electronic device.

In an embodiment, the electronic device ED may include a folding area FA and a plurality of non-folding areas NFA1, NFA2, where the non-folding areas NFA1, NFA2 may include a first non-folding area NFA1 and a second non-folding area NFA2. The folding area FA may be disposed between the first non-folding area NFA1 and the second non-folding area NFA2. The first non-folding area NFA1, the folding area FA, and the second non-folding area NFA2 may be arranged to be directed in the second direction DR2.

In an embodiment, for example, although one folding area FA and two non-folding areas NFA1, NFA2 are shown, the number of folding areas FA and non-folding areas NFA1, NFA2 is not limited thereto. For instance, the electronic device ED may include a plurality of non-folding areas and a plurality of folding areas (more than two folding areas) disposed between the non-folding areas.

In an embodiment, the electronic device ED may have a top surface defined as a display surface DS and may have a plane defined by the first direction DR1 and the second direction DR2. Images IM generated by the electronic device ED may be provided to the user through the display surface DS.

In an embodiment, the display surface DS may include a display area DA and a non-display area NDA surrounding the display area DA, where the display area DA may display images and the non-display area NDA may not display images. The non-display area NDA may surround the display area DA and define an edge of the electronic device ED, which may be printed in a predetermined color.

Although not shown, in an embodiment, the electronic device ED may include a plurality of sensors, including at least one camera.

In an embodiment and referring to FIG. 5, the electronic device ED may be a foldable electronic device that may be folded or unfolded. For example, the folding area FA may bend around a folding axis FX which is directed parallel to the first direction DR1, allowing the electronic device ED to be folded. The folding axis FX may be defined as a short axis directed parallel to a short side of the electronic device ED.

In an embodiment, when the electronic device ED is folded, the first non-folding area NFA1 and the second non-folding area NFA2 may face each other, and the electronic device ED may be in-folded so that the display surface DS is not exposed to the outside. However, the invention is not limited thereto. For example, in another embodiment, the electronic device ED may also be out-folded around the folding axis FX such that the display surface DS is exposed to the outside.

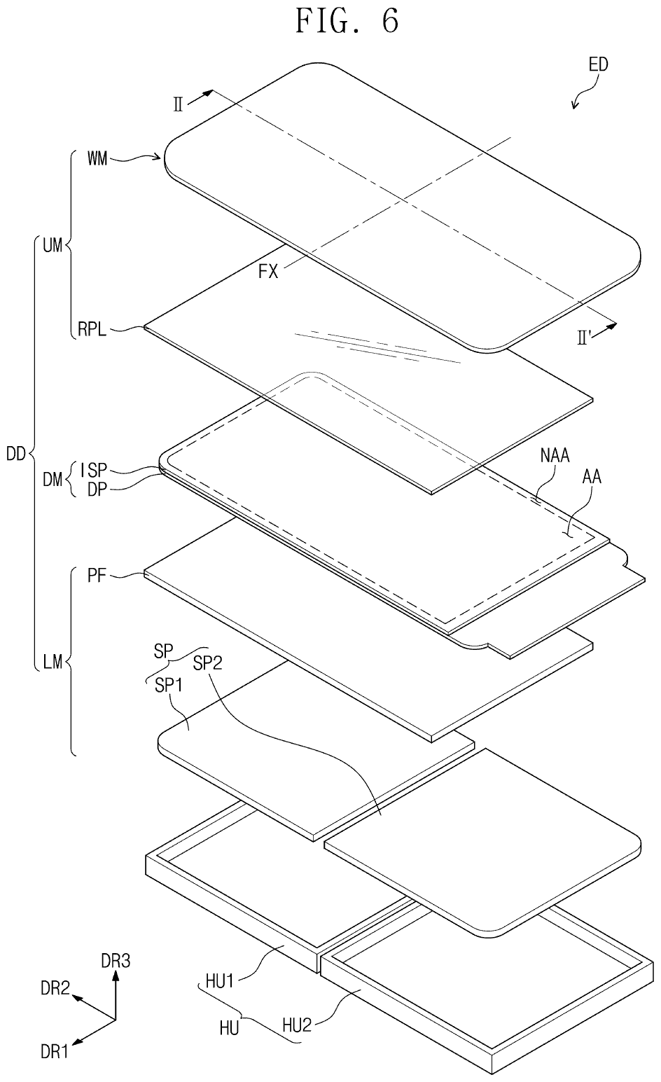

FIG. 6 is an exploded perspective view of the electronic device shown in FIG. 4, according to an embodiment.

In an embodiment and referring to FIG. 6, the electronic device ED includes a display device DD and a housing HU. Although not shown, in another embodiment, the electronic device ED may further include a mechanical structure of controlling a folding operation of the display device DD.

In an embodiment, the display device DD may include a display module DM that displays images, an upper module UM disposed on the display module DM, and a lower module LM disposed below the display module DM. The display module DM constitutes a part of the display device DD, and, in particular, images may be generated by the display module DM. The display module DM may display images according to electrical signals and transmit/receive information related to external input. The display module DM may be defined by an active area AA and a peripheral area NAA. The active area AA may be defined as an area that outputs the images provided by the display module DM.

In an embodiment, the peripheral area NAA is disposed adjacent to the active area AA. For example, the peripheral area NAA may surround the active area AA. However, this is shown as an example, and the peripheral area NAA may be defined in various shapes and is not limited to any one embodiment. According to an embodiment, the active area AA of the display module DM may overlap at least one portion of the display area DA in FIG. 4.

In an embodiment, the display module DM may include a display panel DP and an input sensing unit ISP. The display panel DP, according to an embodiment, may be a light-emitting display panel and is not particularly limited to any one embodiment. For example, the display panel DP may be an organic light-emitting display panel, an inorganic light-emitting display panel, or a quantum dot light-emitting display panel. The light-emitting layer of the organic light-emitting display panel may include an organic light-emitting material, while the light-emitting layer of the inorganic light-emitting display panel may include an inorganic light-emitting material. The light-emitting layer of the quantum dot light-emitting display panel may include quantum dots and quantum rods. Hereinafter, the display panel DP will be described as an organic light-emitting display panel.

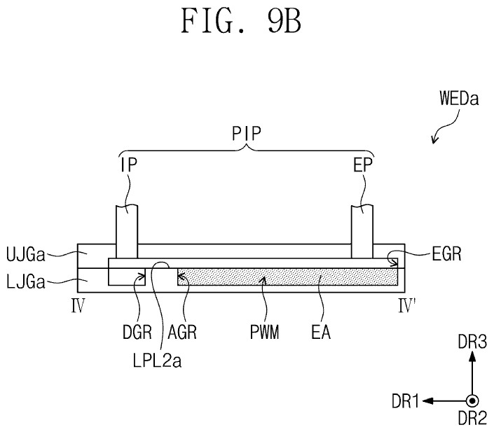

In an embodiment, the display panel DP may be a flexible display panel. Accordingly, the display panel DP may be entirely rolled up or folded and unfolded around the folding axis FX (see FIG. 9).

In an embodiment, the input sensing unit ISP may be directly disposed on the display panel DP. According to an embodiment, the input sensing unit ISP may be formed on the display panel DP by a continuous process. That is, when the input sensing unit ISP is directly disposed on the display panel DP, an adhesive film is not disposed between the input sensing unit ISP and the display panel DP. However, the invention is not limited thereto. An adhesive film may be disposed between the input sensing unit ISP and the display panel DP. In this case, the input sensing unit ISP is not manufactured by a continuous process but is instead manufactured through a separate process and then fixed to a top surface of the display panel DP by the adhesive film.

In an embodiment, the display panel DP generates images, and the input sensing unit ISP acquires coordinate information with respect to user input (e.g., touch events).

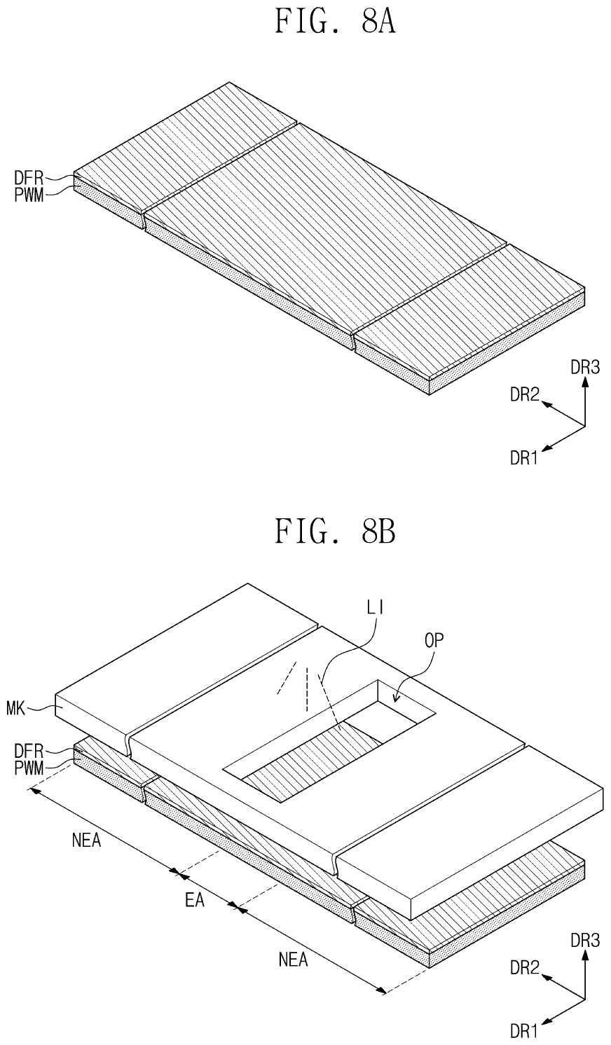

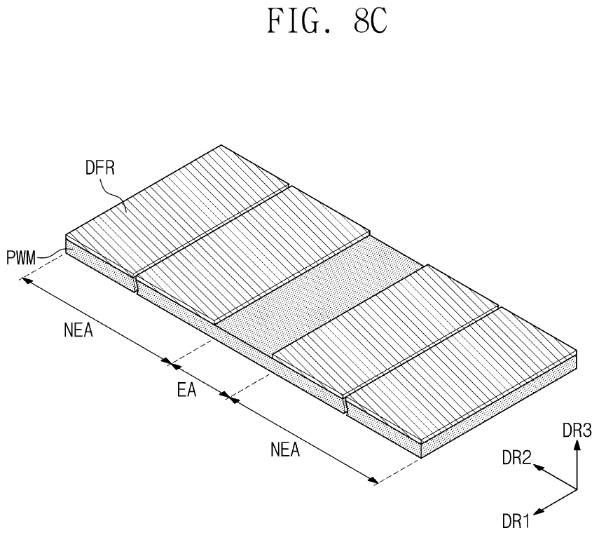

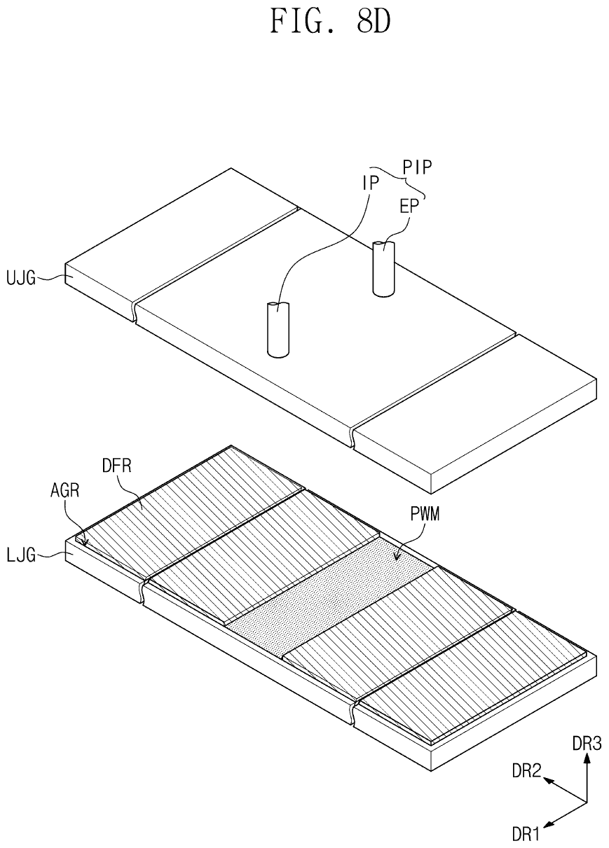

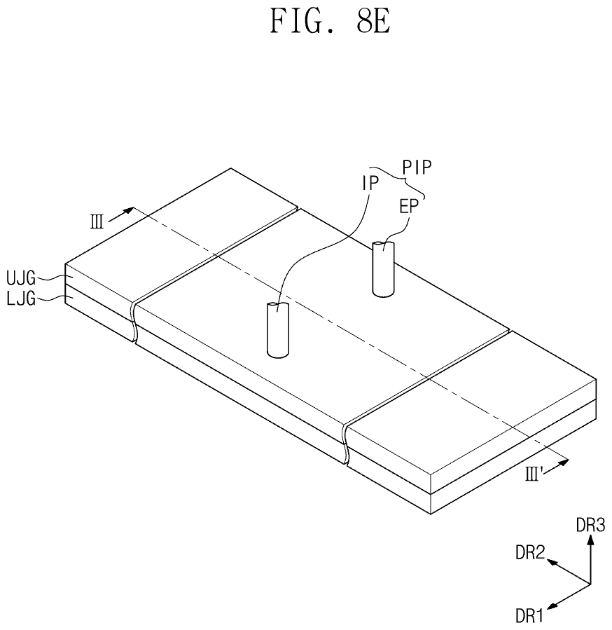

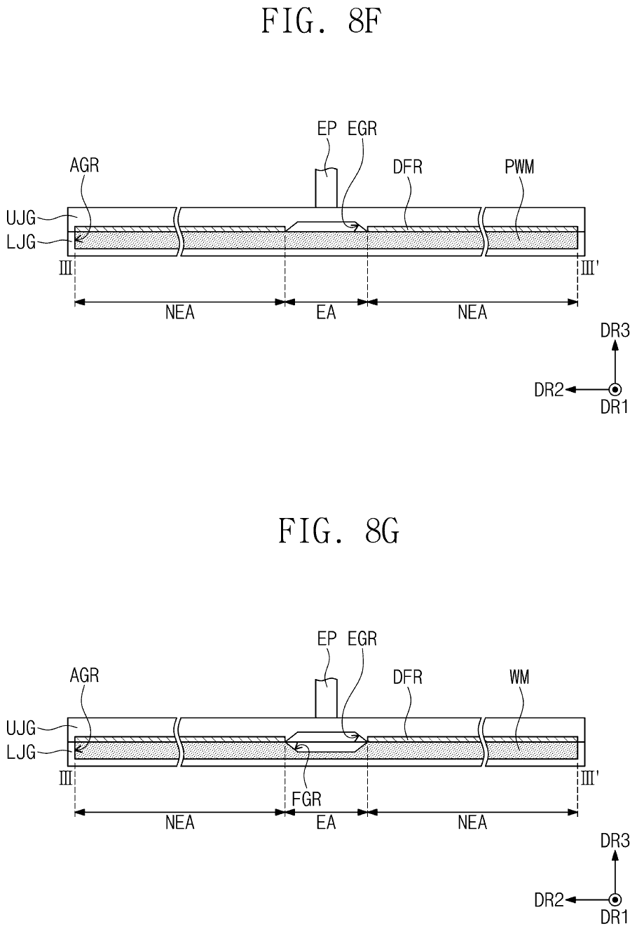

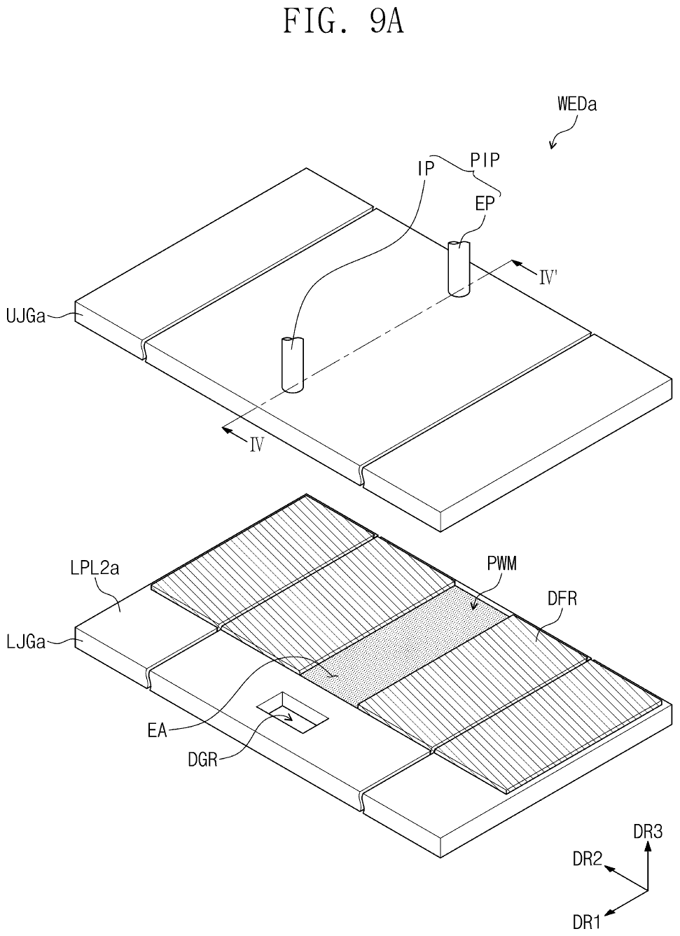

In an embodiment, the upper module UM may include a cover window WM disposed on the display module DM, where the cover window WM may include an optically transparent insulating material. Accordingly, the images generated by the display module DM may be easily perceived by the user through the cover window WM. A process of manufacturing the cover window WM will be described in detail with reference to FIGS. 8A to 8G.

In an embodiment, the upper module UM may further include one or more functional layers disposed between the display module DM and the cover window WM. In an embodiment, the functional layer may be an anti-reflection layer RPL that blocks external light reflections.

In an embodiment, the anti-reflection layer RPL may prevent an issue where the elements constituting the display module DM are viewed from the outside by external light incident through the front surface of the display device DD from occurring. The anti-reflection layer RPL may include a retarder and a polarizer, where the retarder may be a film type or a liquid crystal coating type and may include a λ/2 retarder and/or a λ/4 retarder. The polarizer may also be a film type or a liquid crystal coating type. The film type may include a stretched synthetic resin film, and the liquid crystal coating type may include liquid crystals arranged in a predetermined alignment. The retarder and polarizer may be implemented as a single polarizing film. The functional layer may further include a protective film disposed on or below the anti-reflection layer RPL.

In an embodiment, the lower module LM may include a support plate SP disposed on a back surface of the display module DM to support the display module DM, and a protective film PF disposed between the display module DM and the support plate SP. The support plate SP may include support plates having a number corresponding to that of the non-folding areas NFA1, NFA2 (see FIG. 4). In an embodiment, the support plate SP may include a first support plate SP1 and a second support plate SP2 spaced apart from the first support plate SP1.

In an embodiment, the support plates SP1, SP2 may be disposed to correspond to the non-folding areas NFA1, NFA2 (see FIG. 4), respectively. The first support plate SP1 may be disposed to overlap the first non-folding area NFA1 (see FIG. 4), and the second support plate SP2 may be disposed to overlap the second non-folding area NFA2 (see FIG. 4) of the display module DM. Each of the support plates SP1, SP2 may include a metal material or a plastic material.

In an embodiment, when the electronic device ED is in an unfolded state, as shown in FIG. 4, the support plates SP1, SP2 may be spaced apart from each other in the first direction DR1. When the electronic device ED is in a folded state around the folding axis FX, as shown in FIG. 5, the support plates SP1, SP2 may be spaced apart from each other in the third direction DR3.

In an embodiment, the support plates SP1, SP2 may be disposed to be spaced apart from each other corresponding to the folding area FA (see FIG. 4). The support plates SP1, SP2 may partially overlap the folding area FA (see FIG. 4). That is, a distance between the support plates SP1, SP2 in the second direction DR2 may be less than a width of the folding area FA (see FIG. 4).

Although not shown, in an embodiment, the support plate SP may further include a connection module to connect the support plates SP1, SP2 to each other, where the connection module may include a hinge module or a multi-joint module.

In an embodiment, although the support plate SP is shown as having two support plates SP1, SP2, the invention is not limited thereto. That is, if a plurality of folding axes FX are provided, the support plate SP may include a plurality of support plates separated by the plurality of folding axes FX (see FIG. 5). Additionally, in another embodiment, the support plate SP may be provided as an integral structure, without being separated into the support plates SP1, SP2. In this case, a bending part may be provided in the support plate SP corresponding to the folding area FA (see FIG. 4). The bending part may include an opening defined through the support plate SP or a groove recessed from one surface of the support plate SP.

In an embodiment, the protective film PF may be disposed between the display module DM and the support plate SP, where the protective film PF may be disposed below the display module DM to protect the back surface of the display module DM. The protective film PF may include a synthetic resin film, such as a polyimide film or a polyethylene terephthalate film. However, this is an example, and the protective film PF is not limited thereto.

In an embodiment, the housing HU may be coupled to the display device DD, particularly the cover window WM, and may accommodate the display module DM and the lower module LM therein. The housing HU is shown as including separated first and second housings HU1, HU2, respectively, however, the invention is not limited thereto. Although not shown, the electronic device ED may further include a hinge structure for connecting the housings HU1, HU2 to each other.

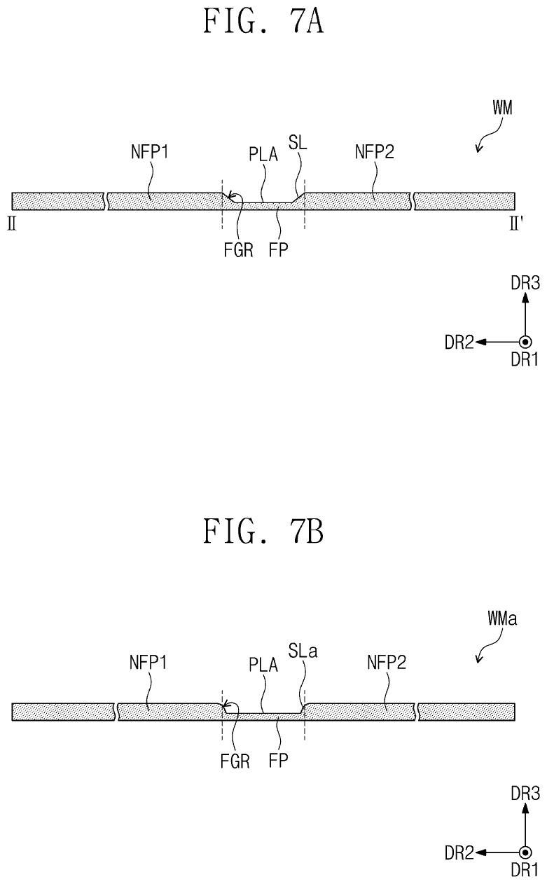

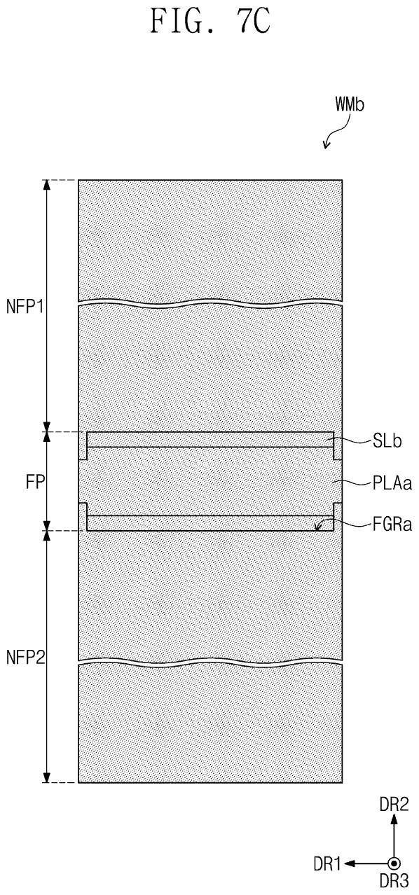

FIGS. 7A to 7C are cross-sectional views of the cover window shown in FIG. 4, according to an embodiment.

For example, FIGS. 7A and 7B are cross-sectional views of a portion corresponding to line II-II′ shown in FIG. 6, and FIG. 7C is a plan view of the cover window WMb, according to an embodiment.

In an embodiment and referring to FIG. 7A, the cover window WM may include a first non-folding part NFP1, a second non-folding part NFP2, and a folding part FP, where the folding part FP may be disposed between the first non-folding part NFP1 and the second non-folding part NFP2. The first non-folding part NFP1, the folding part FP, and the second non-folding part NFP2 may be arranged in the second direction DR2.

In an embodiment, the first non-folding part NFP1 may overlap the first non-folding area NFA1 of FIG. 4. The second non-folding part NFP2 may overlap the second non-folding area NFA2 of FIG. 4. The folding part FP may overlap the folding area FA of FIG. 4.

In an embodiment, a folding groove FGR may be defined in a top surface of the folding part FP and may extend from the top surface of the folding part FP toward a bottom surface of the folding part FP. For example, the folding groove FGR may have a shape corresponding to that of a portion of a trapezoid.

In an embodiment, the folding part FP may have a thickness that is less than that of each of the first non-folding part NFP1 and the second non-folding part NFP2. The height of the top surface of the folding part FP may be lower than that of a top surface of each of the first non-folding part NFP1 and the second non-folding part NFP2.

In an embodiment, since the thickness of the folding part FP is less than that of each of the first non-folding part NFP1 and the second non-folding part NFP2, the folding part FP of the cover window WM may be easily folded when the display device DD (see FIG. 4) is folded.

In an embodiment, since the thicknesses of the first non-folding part NFP1 and the second non-folding part NFP2 are greater than the thickness of the folding part FP, the first non-folding part NFP1 and the second non-folding part NFP2 may have greater rigidity than that of the folding part FP.

In an embodiment, the folding part FP may include a flat part PLA and side surfaces SL disposed on an inner surface thereof that define the folding groove FGR. The flat part PLA may have a plane defined by the first direction DR1 and the second direction DR2. The side surfaces SL may extend from both sides of the flat part PLA, which oppose each other in the second direction DR2 toward the top surfaces of the first non-folding part NFP1 and the second non-folding part NFP2. When viewed from the first direction DR1, the side surfaces SL may be straight. An angle defined between the side surfaces SL and the flat part PLA may be an obtuse angle.

In an embodiment, the cover window WM may be manufactured using the upper jig UJG shown in FIGS. 1 and 2. The manufacturing process of the cover window WM will be described in detail below.

In an embodiment and referring to FIG. 7B, a cover window WMa may have a curved surface at a boundary between the side surfaces SLa and the non-folding parts NFP1, NFP2. The boundary between the side surfaces SLa and the non-folding parts NFP1, NFP2 may be a convex curved surface toward the top. When viewed from the first direction DR1, the boundaries between the folding part FP and the first non-folding part NFP1 and between the folding part FP and the second non-folding part NFP2 may have a predetermined curvature.

Accordingly, in an embodiment, when light provided by the display panel DP refracts and passes through the boundaries between the folding part FP and the first non-folding part NFP1, as well as between the folding part FP and the second non-folding part NFP2, it may prevent the light path from abruptly changing. Therefore, it may prevent the boundaries between the folding part FP and the first non-folding part NFP1, as well as between the folding part FP and the second non-folding part NFP2, from being visible to the user due to light.

In an embodiment and referring to FIG. 7C, the width of the flat part PLAa in the second direction DR2 may be variable. The width in the second direction DR2 at both ends of the flat part PLAa, which oppose each other in the first direction DR1, may be less than the width in the second direction DR2 at the center of the flat part PLAa.

In an embodiment, the side surfaces SLb may have a length in the first direction DR1 that is shorter than that of the flat part PLAa in the first direction DR1. Both ends of the flat part PLAa, which oppose each other in the first direction DR1, may not be disposed between the side surfaces SLb.

In an embodiment, the width of the folding groove FGRa in the second direction DR2 may be variable. The width in the second direction DR2 at both ends of the folding groove FGRa, which oppose each other in the first direction DR1, may be less than the width in the second direction DR2 at the center of the folding groove FGRa. The center of the folding groove FGRa may be defined as a point that is equidistant from both ends of the folding groove FGRa.

As a result, in an embodiment, the rigidity of both sides of the folding part FP, which oppose each other in the first direction DR1, may increase. Therefore, even if external impacts are applied to both sides of the folding part FP, which oppose each other in the first direction DR1, the sides of the folding part FP may not be damaged.

FIGS. 8A to 8G are views for explaining a method for manufacturing the cover window using the apparatus for etching the cover shown in FIG. 1, according to an embodiment.

For example, FIGS. 8A to 8E are illustrated in perspective views, and FIGS. 8F and 8G are cross-sectional views of a portion corresponding to line III-III′ shown in FIG. 8E, according to an embodiment.

Among the elements shown in FIGS. 8A to 8G, the description of elements that are the same as those described with reference to the previous drawings will be omitted or simplified.

In an embodiment and referring to FIG. 8A, the method for manufacturing the cover window may include a step of preparing a preliminary cover window PWM. A dry film resist DFR may be disposed on the preliminary cover window PWM and may include a polymer material. For example, the dry film resist DFR may include polyimide (PI) or epoxy.

In an embodiment and referring to FIG. 8B, after the dry film resist DER is disposed on the preliminary cover window PWM, a mask MK may be disposed on the dry film resist DFR, where the mask MK may define an opening OP. An opening OP may be defined in the mask MK.

In an embodiment, a portion of the dry film resist DFR may overlap the opening OP. A portion of the preliminary cover window PWM may also overlap the opening OP. Hereinafter, the portion of the preliminary cover window PWM that overlaps the opening OP may be defined as an etching area EA. A portion of the preliminary cover window PWM that does not overlap the opening OP may be defined as non-etching areas NEA. The etching area EA may be disposed between the non-etching areas NEA.

In an embodiment, after the mask MK is disposed, a light source may be disposed on the mask MK. An exposure process may be carried out using the light LI emitted from the light source. The light LI may be irradiated onto the portion of the dry film resist DFR that is exposed through the opening OP of the mask MK. The molecular composition or components of the dry film resist DFR exposed to the light may be altered.

In an embodiment and referring to FIGS. 8B and 8C, after the exposure process is completed, the portion of the dry film resist DFR that was exposed to the light may be removed from the preliminary cover window PWM. The etching area EA may be exposed to the outside from the dry film resist DFR.

In an embodiment and referring to FIGS. 2, 8D, and 8E, the preliminary cover window PWM may be disposed inside the accommodation groove AGR. After the preliminary cover window PWM is disposed inside the accommodation groove AGR, the upper jig UJG may move toward the lower jig LJG in the third direction DR3 to cover the preliminary cover window PWM.

In an embodiment and referring to FIGS. 3A, 8E, and 8F, after the upper jig UJG is disposed on the preliminary cover window PWM, the etchant may be introduced into the etching groove EGR through the first opening OP1 connected to the inlet pipe IP.

In an embodiment and as shown in FIG. 8F, the etching groove EGR may be sealed by the upper jig UJG and the preliminary cover window PWM. Accordingly, even when the etchant is introduced into the etching groove EGR, the etchant may not leak to the outside of the upper jig UJG and the lower jig LJG. Therefore, the safety of the etching process may be improved.

In an embodiment, the etchant introduced into the etching groove EGR may be discharged to the outlet pipe EP through the second opening OP2. The etchant may be introduced from the first opening OP1 to flow in one direction toward the second opening OP2. For example, the etchant may flow in the first direction DR1. When the etchant flows in the first direction DR1, the etching area EA, which is exposed from the dry film resist DFR, may be etched.

When the etching area EA is etched, residues may be generated on a surface of the etching area EA. However, since the etchant flows in one direction, the residues may be peeled off from the surface of the etching area EA by the etchant. Therefore, the residues may be easily removed from the surface of the preliminary cover window PWM.

In an embodiment and referring to FIGS. 8F and 8G, the etching area EA may be etched to define a folding groove FGR. An amount of etching in the etching area EA may vary depending on the curvature of the folding part FP and the thickness of the cover window WM in the folded state of the electronic device ED (see FIG. 4). In other words, the shape of the cover window WM may be modified according to the folding characteristics of the electronic device ED (see FIG. 4).

In an embodiment, the folding groove FGR may have a shape corresponding to that of the etching groove EGR. The shape of the folding groove FGR and the etching groove EGR may be symmetrical to each other in the third direction DR3. For example, the folding groove FGR may have a shape corresponding to a portion of a trapezoid. Accordingly, when the folding characteristics of the electronic device ED change, the shape of the etching groove EGR may be adjusted, allowing the cover window WM with various shapes to be easily manufactured. The preliminary cover window PWM, in which the folding groove FGR is defined, may be defined as the cover window WM.

In an embodiment, the dry film resist DFR may prevent the etchant from flowing into the non-etching areas NEA. Thus, the non-etching areas NEA may not be etched due to the presence of the dry film resist DFR.

FIG. 9A is a perspective view of an apparatus for etching a cover window, according to an embodiment. FIG. 9B is a cross-sectional view of a portion corresponding to line IV-IV′ shown in FIG. 9A, according to an embodiment.

In an embodiment, for example, in FIG. 9A, an upper jig UJGa is in a state separated from a lower jig LJGa, while in FIG. 9B, the upper jig UJGa is in a state disposed on the lower jig LJGa.

Among the elements shown in FIGS. 9A and 9B, the description of elements that are the same as those described with reference to the previous drawings will be omitted or simplified.

In an embodiment and referring to FIGS. 9A and 9B, a buffer groove DGR may be defined in a second top surface LPL2a of the lower jig LJGa. The buffer groove DGR may be arranged in the first direction DR1 along with the accommodation groove AGR. The buffer groove DGR may be disposed adjacent to the etching area EA in the first direction DR1. The length of the buffer groove DGR in the second direction DR2 may be substantially the same as the length of the etching area EA in the second direction DR2.

In an embodiment and referring to FIGS. 3A and 9B, when the etchant is introduced into the etching groove EGR through the first opening OP1, the flow rate of the etchant may change abruptly at the boundary between the first opening OP1 and the etching groove EGR. As a result, the etchant may generate a vortex through rotational motion within the etching groove EGR disposed adjacent to the first opening OP1. The vortex may increase the contact between the etchant and the etching area EA.

Therefore, in an embodiment, when the etchant is directly injected into the etching area EA from the first opening OP1, an amount of etching in the etching area EA disposed adjacent to the first opening OP1 may be greater than that of etching in the etching area EA disposed farther from the first opening OP1. Consequently, the etching amount in the etching area EA may not be uniform.

However, in an embodiment, a buffer groove DGR may be defined in the lower jig LJGa. The etchant may be introduced into the buffer groove DGR through the first opening OP1. When the height of the etchant filled in the buffer groove DGR exceeds the height of the second top surface LPL2a, the etchant may flow toward the etching groove EGR. As a result, the etchant in the etching groove EGR may not generate a vortex. Therefore, the etching amount in the etching area EA may be uniform.

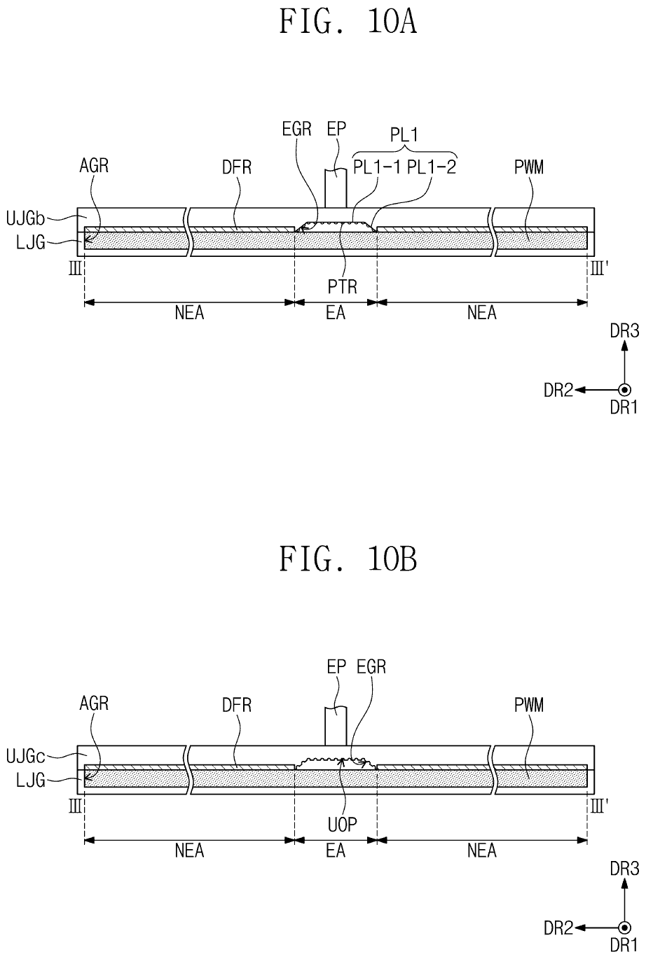

FIGS. 10A and 10B are cross-sectional views illustrating an upper jig, according to an embodiment.

For example, FIGS. 10A and 10B are cross-sectional views of a portion corresponding to line III-III′ shown in FIG. 8E, according to an embodiment.

Among the elements shown in FIGS. 10A and 10B, the description of elements that are the same as those described with reference to the previous drawings will be omitted or simplified.

In an embodiment and referring to FIG. 10A, an upper jig UJGb may include a plurality of pattern parts PTR which may be disposed within the etching groove EGR. The pattern parts PTR may be disposed on the first surface PL1. The pattern parts PTR may be disposed on at least one of the (1-1)-th surface PL1-1 or the (1-2)-th surfaces PL1-2. For example, the pattern parts PTR may be disposed on both the (1-1)-th surface PL1-1 and the (1-2)-th surfaces PL1-2.

In an embodiment, since the pattern parts PTR are disposed within the etching groove EGR, the flow of the etchant within the etching groove EGR may become non-linear. The etchant may flow irregularly within the etching groove EGR due to the pattern parts PTR and may be turbulent.

In an embodiment, as a result, the diffusivity of the etchant may relatively increase, thereby enhancing the etching efficiency of the etchant. Additionally, when the preliminary cover window PWM (see FIG. 12G) is etched, residue is generated on the surface of the preliminary

In an embodiment and referring to FIG. 10B, a plurality of uneven grooves UOP may be defined in the first surface PL1, where the uneven grooves UOP may be defined continuously with the etching groove EGR. The uneven grooves UOP may be disposed on at least one of the (1-1)-th surface PL1-1 or the (1-2)-th surfaces PL1-2. For example, the uneven grooves UOP may be disposed on both the (1-1)-th surface PL1-1 and the (1-2)-th surfaces PL1-2.

In an embodiment, since the uneven grooves UOP are defined within the etching groove EGR, the flow of the etchant within the etching groove EGR may be turbulent and the etchant may flow irregularly within the etching groove EGR due to the uneven grooves UOP.

In an embodiment, as a result, the diffusivity of the etchant may relatively increase, thereby improving the etching efficiency of the etchant. Additionally, when etching the preliminary cover window PWM (see FIG. 12G), residue generated on the surface of the preliminary cover window PWM may be easily removed by the etchant.

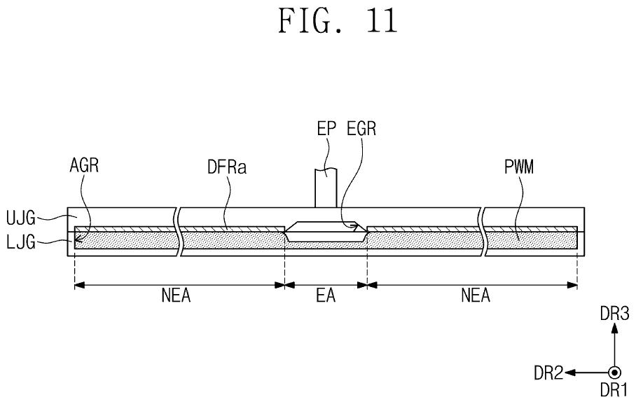

FIG. 11 is a view for explaining the dry film resist, according to an embodiment.

In an embodiment and referring to FIGS. 7B and 11, a portion of dry film resist DFRa disposed adjacent to the etching area EA may have weaker adhesion compared to a portion of the dry film resist DFRa that is spaced apart from the etching area EA.

As a result, the etchant may seep between the portion of the dry film resist DFRa disposed adjacent to the etching area EA and the preliminary cover window PWM. Consequently, the non-etching areas NEA disposed adjacent to the etching area EA may also be etched. The etching area EA and the adjacently disposed non-etching areas NEA may be etched and may result in the manufacturing of a cover window WMb as shown in FIG. 7B.

FIGS. 12A and 12B are views illustrating an upper jig, according to an embodiment.

For example, FIG. 12A is a plan view of a bottom surface of an upper jig UJGd, according to an embodiment, and FIG. 12B is a cross-sectional view of the upper jig UJGd shown in FIG. 12A, according to an embodiment, viewed from the first direction DR1.

Among the elements shown in FIGS. 12A and 12B, the description of elements that are the same as those described with reference to the previous drawings will be omitted or simplified.

In an embodiment and referring to FIGS. 12A and 12B, a plurality of coupling grooves BGR may be defined in a bottom surface PL of the upper jig UJGd. The coupling grooves BGR may be defined as recessed spaces extending from the bottom surface PL of the upper jig UJGd toward a top surface of the upper jig UJGd. Blocking parts BL, described later, may be disposed in the coupling grooves BGR. The coupling grooves BGR may be defined in the second surface PL2 and may be defined adjacent to both sides of the etching groove EGR in the second direction DR2. The coupling grooves BGR may extend in the first direction DR1 and may be spaced apart from each other in the second direction DR2. When viewed from the first direction DR1, the coupling grooves BGR may have a shape corresponding to a portion of a circle.

In an embodiment, the upper jig UJGd may further include a plurality of blocking parts BL, where the blocking parts BL may be disposed on the bottom surface PL of the upper jig UJGd. Each of the blocking parts BL may be disposed inside a corresponding one of the coupling grooves BGR defined in the second surface PL2. When viewed on the plane, the blocking parts BL may extend in the first direction DR1 and may be spaced apart from each other in the second direction DR2.

For example, in an embodiment, the blocking parts BL may include elastic rubber. However, the material of the blocking parts BL is not limited thereto. The blocking parts BL may prevent the etchant from leaking out of the etching groove EGR (see FIG. 8F). Accordingly, it may prevent the non-etching areas NEA (see FIG. 8F) of the preliminary cover window PWM (see FIG. 8F) from being etched.

In an embodiment, the blocking parts BL may be disposed adjacent to both sides of the etching groove EGR, which oppose each other in the second direction DR2. When viewed on the plane, the blocking parts BL may be disposed adjacent to one side of the (1-2)-th surfaces PL1-2.

In an embodiment, when viewed from the first direction DR1, the blocking parts BL may have a circular shape. Substantially, the blocking parts BL may have a cylindrical shape extending in the first direction DR1. However, the shape of the blocking parts BL is not limited thereto.

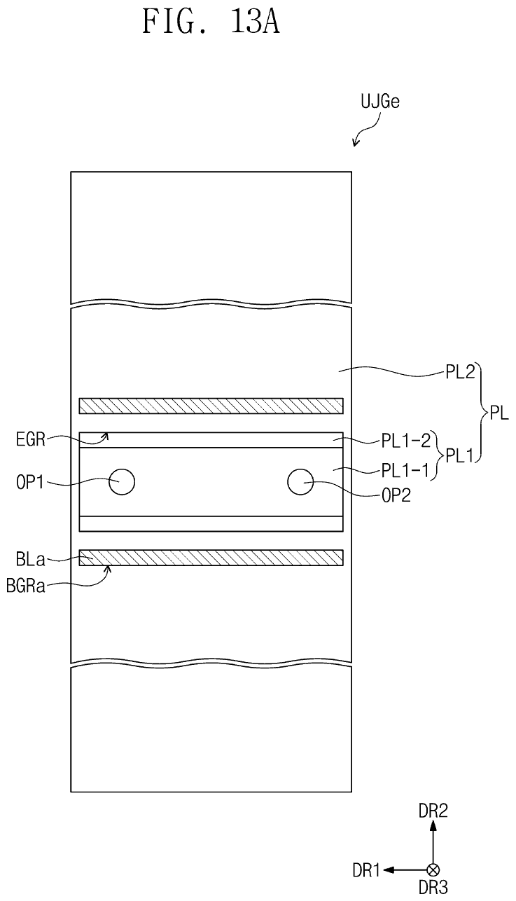

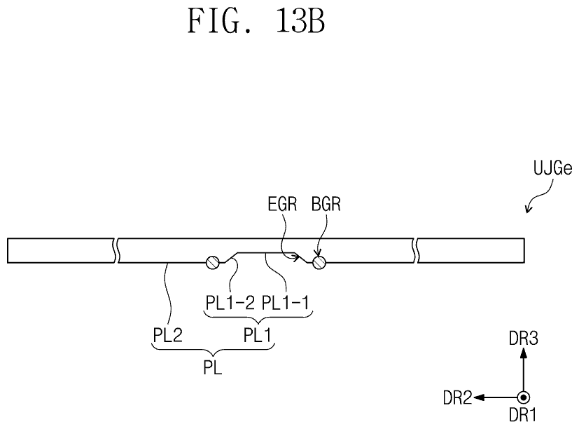

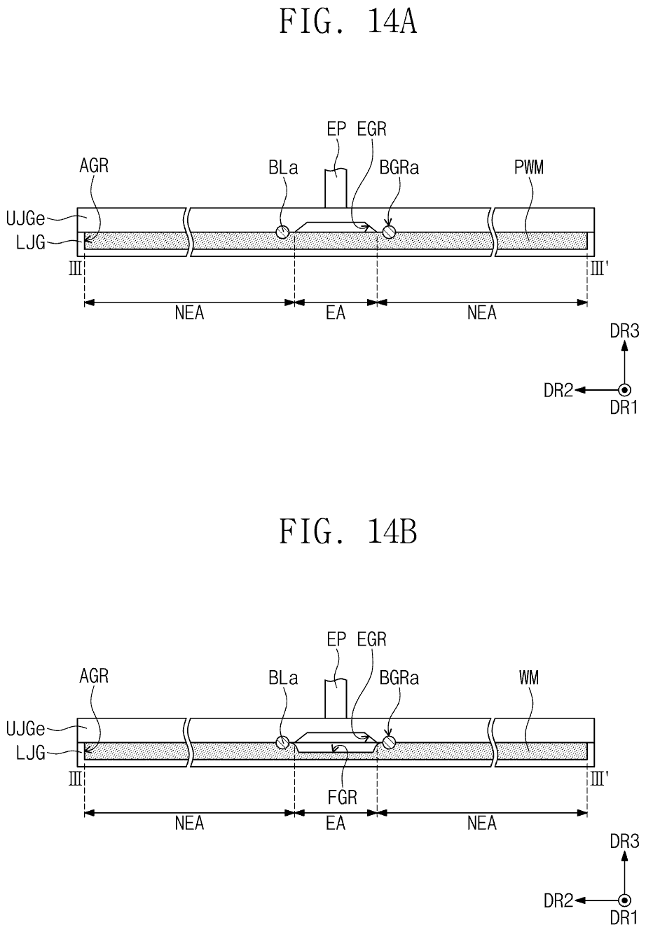

FIGS. 13A and 13B are views illustrating the upper jig UJGe, according to an embodiment. FIGS. 14A and 14B are views for explaining the etching of the preliminary cover window using the upper jig UJG3 shown in FIGS. 13A and 13B.

For example, FIG. 13A is a plan view of a bottom surface of an upper jig UJGe, according to an embodiment, and FIG. 13B is a cross-sectional view of the upper jig UJGe shown in FIG. 13A, according to an embodiment, viewed from the first direction DR1.

For example, FIGS. 14A and 14B are cross-sectional views of a portion corresponding to line III-III′ shown in FIG. 8E, according to an embodiment.

Among the elements shown in FIGS. 13A through 14B, the description of elements that are the same as those described with reference to the previous drawings will be omitted or simplified.

In an embodiment and referring to FIGS. 13A and 13B, coupling grooves BGRa may be defined at a predetermined distance from both sides of the etching groove EGR in the second direction DR2, which oppose each other in the second direction DR2.

In an embodiment, when viewed on the plane, blocking parts BLa may be disposed at a predetermined distance from both sides of the etching groove EGR in the second direction DR2, which oppose each other in the second direction DR2. When viewed on the plane, the blocking parts BLa may be spaced apart from one side of the (1-2)-th surfaces PL1-2 in the second direction DR2.

In an embodiment and referring to FIGS. 7B, 14A, and 14B, since the blocking parts BLa are spaced apart from the etching groove EGR, the etchant may leak into the non-etching areas NEA. As a result, a portion of the non-etching areas NEA may be etched. The etching area EA and the non-etching areas NEA disposed adjacent to the etching area EA may be etched to produce the cover window WMb shown in FIG. 7B.

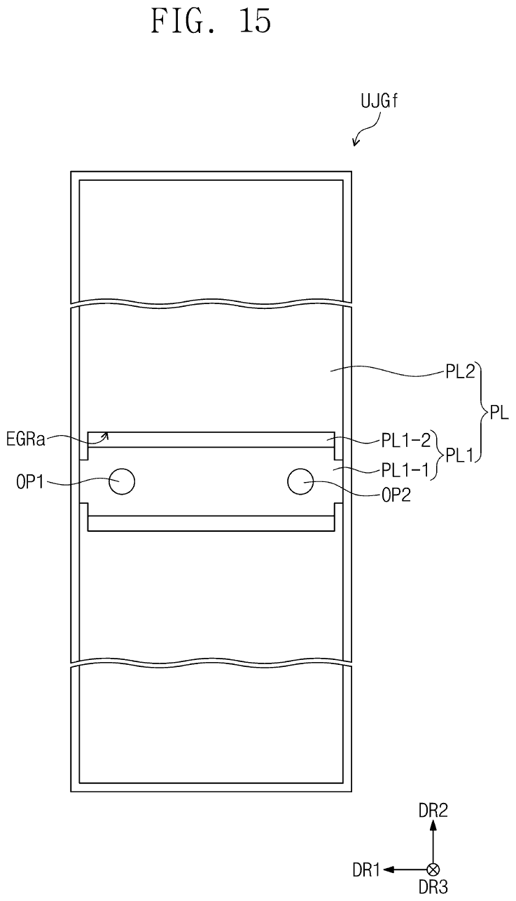

FIG. 15 is a plan view illustrating a bottom surface of an upper jig, according to an embodiment.

Among the elements shown in FIG. 15, the description of elements that are the same as those described with reference to the previous drawings will be omitted or simplified.

In an embodiment and referring to FIG. 15, the length of an etching groove EGRa in the second direction DR2 may be variable. The length in the second direction DR2 at both ends of the etching groove EGRa, which oppose each other in the first direction DR1, may be less than the length of the center of the etching groove EGRa in the second direction DR2. The center of the etching groove EGRa may be defined as a point that is equidistant from both ends of the etching groove EGRa.

In an embodiment, when viewed on the plane, the length of the (1-1)-th surface PL1-1 in the first direction DR1 may be greater than the length of the (1-2)-th surfaces PL1-2 in the first direction DR1.

In an embodiment and referring to FIGS. 7C and 15, when performing the etching process using an upper jig UJGf, the shape of the folding groove FGR defined in the preliminary cover window PWM (see FIG. 8F) may be symmetrical to the shape of the etching groove EGRa in the third direction DR3. Accordingly, the cover window WMb of FIG. 7C may be manufactured.

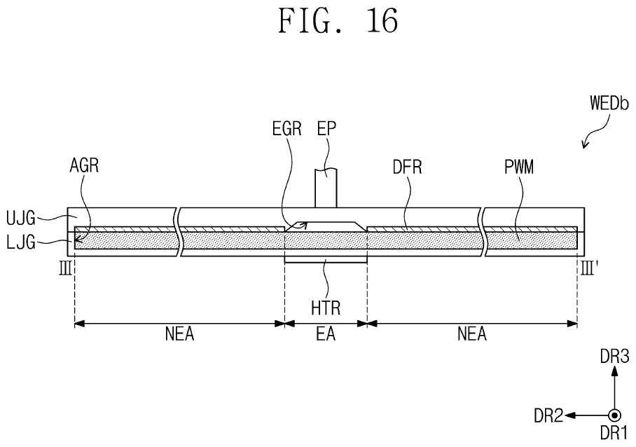

FIG. 16 is a view for explaining an etching device, according to an embodiment.

For example, FIG. 16 is a cross-sectional view of a portion corresponding to line III-III′ shown in FIG. 8E, according to an embodiment.

Among the elements shown in FIG. 16, the description of elements that are the same as those described with reference to the previous drawings will be omitted or simplified.

In an embodiment and referring to FIG. 16, an apparatus WEDb for etching a cover window may further include a heater HTR, where the heater HTR may be disposed on the bottom surface of the lower jig LJG. The heater HTR may overlap the etching groove EGR.

In an embodiment, the heater HTR may adjust the temperature of the etchant flowing within the etching groove EGR, thereby controlling the amount of etching on the preliminary cover window PWM.

According to an embodiment, the cover window may be etched in a shape that is symmetrical to the shape of the etching groove defined in the bottom surface of the upper jig, thereby forming a folding groove. Consequently, when the folding characteristics of the display device are altered and the shape of the cover window changes, it is possible to easily manufacture cover windows having different shapes from each other by replacing the upper jig having a modified etching groove shape.

According to an embodiment of the invention, the etchant may be introduced into the etching groove through the inlet pipe to flow toward the outlet pipe in one direction. As a result, any residues generated on the surface of the cover window may be removed from the surface by the flow of the etchant. Therefore, the residues may be easily removed from the surface of the cover window.

While the invention has been described with reference to embodiments thereof, it will be apparent to those of ordinary skill in the art that various changes and modifications may be made thereto without departing from the spirit and scope of the invention. In addition, embodiments disclosed herein are not intended to limit the technical spirit of the invention, and all technical spirits within the scope of the invention and a scope equivalent thereto should be interpreted as being included in the scope of the invention. Accordingly, embodiments disclosed herein are not intended to limit the technical spirit of the invention, and all technical ideas disclosed herein should be construed as being included in the scope of the invention. Moreover, embodiments or parts of the embodiments may be combined in whole or in part without departing from the scope of the invention.

What is claimed is:

1. An apparatus for etching a cover window for a display device, the apparatus comprising:
a lower jig in which an accommodation groove is defined, wherein a cover window made of a glass material is disposed within the accommodation groove; and
an upper jig disposed on the lower jig,
wherein a bottom surface of the upper jig, which faces the lower jig and which has first sides extending in a first direction and second sides extending in a second direction intersecting with the first direction, comprises;
a first surface defining an etching groove extending in the first direction; and
a second surface disposed adjacent to the first surface.

2. The apparatus of claim 1, further comprising:
a plurality of pipes disposed on a top surface of the upper jig and spaced apart from each other in the first direction,
wherein the etching groove is defined to be continuous with an internal space of the plurality of pipes.

3. The apparatus of claim 2, wherein the plurality of pipes comprise:
an inlet pipe; and
an outlet pipe spaced apart from the inlet pipe in the first direction.

4. The apparatus of claim 3, wherein a buffer groove, which is spaced apart from the accommodation groove in the first direction and which overlaps the inlet pipe, is defined in a top surface of the lower jig.

5. The apparatus of claim 2, wherein the upper jig further comprises a pattern part disposed on the first surface.

6. The apparatus of claim 2, wherein an uneven groove is defined in the first surface, and
wherein the uneven groove is defined to be continuous with the etching groove.

7. The apparatus of claim 2, wherein the upper jig further comprises a plurality of blocking parts disposed adjacent to both sides of the etching groove, which oppose each other in the second direction intersecting the first direction.

8. The apparatus of claim 2, wherein the upper jig further comprises a plurality of blocking parts spaced apart in the second direction from both sides of the etching groove, which oppose each other in the second direction intersecting the first direction.

9. The apparatus of claim 2, further comprising a heater disposed on a bottom surface of the lower jig.

10. The apparatus of claim 1, wherein, when viewed on a plane, a width of each of both ends of the etching groove in the second direction intersecting the first direction is less than a width of the etching groove at a central portion of the etching groove in the second direction.

11. A method for etching a cover window for a display device, the method comprising:
placing a preliminary cover window in an accommodation groove defined in a lower jig to fix the preliminary cover window, wherein the preliminary cover window comprises non-etching areas arranged in a first direction and an etching area disposed between the non-etching areas;
placing an upper jig on the lower jig to cover the preliminary cover window, wherein the upper jig has an etching groove extending in the first direction defined in a bottom surface thereof facing the lower jig;
introducing an etchant into the etching groove through an inlet pipe disposed on a top surface of the upper jig and connected to the etching groove to etch an etching area; and
discharging the etchant from the etching groove through an outlet pipe disposed on the top surface of the upper jig and spaced apart from the inlet pipe in the first direction,
wherein the bottom surface of the upper jig, which has first sides extending in the first direction and second sides extending in the second direction intersecting with the first direction, comprises;
a first surface defining the etching groove; and
a second surface disposed adjacent to the first surface,
wherein a folding groove is defined in the etched etching area, and wherein the folding groove has a shape corresponding to that of the etching groove.

12. The method of claim 11, further comprising:
placing dry film resist on the preliminary cover window after fixing the preliminary cover window; and
exposing the dry film resist overlapping the etching area to remove the dry film resist from the preliminary cover window,
wherein the dry film resist overlaps the non-etching areas.

13. The method of claim 12, wherein adhesion strength of one side of the dry film resist disposed adjacent to the etching area is weaker than that of an other side of the dry film resist which is spaced apart from the etching area,
wherein the preliminary cover window comprises a curved surface at a boundary between the etched etching area and the non-etching areas.

14. The method of claim 11, wherein the upper jig comprises a plurality of blocking parts disposed adjacent to both sides of the etching groove, wherein the both sides of the etching groove oppose each other in the second direction intersecting the first direction.

15. The method of claim 11, wherein the upper jig further comprises a plurality of blocking parts disposed to be spaced apart from each other in the second direction from both sides of the etching groove, wherein the both sides of the etching groove oppose each other in the second direction intersecting the first direction, and
wherein the preliminary cover window comprises a curved surface at a boundary between the etched etching area and the non-etching areas.

16. The method of claim 11, wherein the upper jig further comprises a pattern part disposed on the first surface.

17. The method of claim 11, wherein an uneven groove is defined in the first surface, and
wherein the uneven groove is defined to be continuous with the etching groove.

18. The method of claim 11, wherein, when viewed on a plane, a width of both ends of the etching groove in the second direction intersecting the first direction is less than a width of the etching groove at a central portion of the etching groove in the second direction.

19. The method of claim 11, wherein the etching of the preliminary cover window further comprises rising a temperature of the etchant through a heater disposed on the bottom surface of the lower jig.

20. The method of claim 11, wherein a buffer groove is defined in a top surface of the lower jig and spaced apart from the accommodation groove in the first direction,
wherein the etchant is introduced from the inlet pipe toward the buffer groove.

21. An electronic device, comprising:
a display device having an etched cover window, wherein the etched cover window was manufactured using an apparatus for etching a cover window for a display device, wherein the apparatus comprises:
a lower jig in which an accommodation groove is defined, wherein a cover window made of a glass material is disposed within the accommodation groove; and
an upper jig disposed on the lower jig,
wherein a bottom surface of the upper jig, which faces the lower jig and which has first sides extending in a first direction and second sides extending in a second direction intersecting with the first direction, comprises:
a first surface defining an etching groove extending in the first direction; and
a second surface disposed adjacent to the first surface.

22. The electronic device of claim 21, wherein the apparatus further comprises:
a plurality of pipes disposed on a top surface of the upper jig and spaced apart from each other in the first direction,
wherein the etching groove is defined to be continuous with an internal space of the plurality of pipes.

23. The electronic device of claim 22, wherein the plurality of pipes comprise:
an inlet pipe; and
an outlet pipe spaced apart from the inlet pipe in the first direction.

24. The electronic device of claim 23, wherein a buffer groove, which is spaced apart from the accommodation groove in the first direction and which overlaps the inlet pipe, is defined in a top surface of the lower jig.

25. The electronic device of claim 22, wherein the upper jig further comprises a pattern part disposed on the first surface.

26. The electronic device of claim 22, wherein an uneven groove is defined in the first surface, and
wherein the uneven groove is defined to be continuous with the etching groove.

27. The electronic device of claim 22, wherein the upper jig further comprises a plurality of blocking parts disposed adjacent to both sides of the etching groove, which oppose each other in the second direction intersecting the first direction.

28. The electronic device of claim 22, wherein the upper jig further comprises a plurality of blocking parts spaced apart in the second direction from both sides of the etching groove, which oppose each other in the second direction intersecting the first direction.

29. The electronic device of claim 22, further comprising a heater disposed on a bottom surface of the lower jig.

30. The electronic device of claim 21, wherein, when viewed on a plane, a width of each of both ends of the etching groove in the second direction intersecting the first direction is less than a width of the etching groove at a central portion of the etching groove in the second direction.
